(19) United States
(12) Patent Application Publication
(10) Pub. No.: US 2009/0166183 A1
(43) Pub. Date: Jul. 2, 2009

(54) METHOD OF MANUFACTURING A PERPENDICULAR MAGNETIC WRITE HEAD WITH STEPPED TRAILING MAGNETIC SHIELD USING COLLIMATED SPUTTER DEPOSITION

(76) Inventors: Yinshi Liu, Foster City, CA (US); Theodore Yong, Fremont, CA (US); Yi Zheng, San Ramon, CA (US)

Correspondence Address: ZILKA-KOTAB, PC- HIT, P.O. BOX 721120, SAN JOSE, CA, 95172-1120, US

(21) Appl. No.: 11/965,981

(22) Filed: Dec. 28, 2007

(51) Int. Cl. C23C 14/46; C25D 3/00; B05D 5/12

(52) U.S. Cl. 204/192.11; 205/80; 427/127

(57) ABSTRACT

A method for manufacturing a magnetic write head having a stepped trailing shield. The stepped trailing shield is formed by forming a non-magnetic bump over a write pole prior to electroplating a wrap-around magnetic shield. This bump is formed by constructing a mask having an opening configured to define the non-magnetic bump. A magnetic material is then sputter deposited. In order to decrease deposition of the magnetic material on the sides of the mask, a collimator is used to align the deposited material along a plane substantially parallel with an air bearing surface plane. This collimation of the deposited magnetic material greatly facilitates liftoff, and more importantly prevents the formation of fences which would otherwise have to be removed by a harsh, aggressive process.

### FIELD OF THE INVENTION

The present invention relates to perpendicular magnetic recording and more particularly to a method for manufacturing a magnetic write head having a stepped trailing shield structure for improved magnetic performance.

### BACKGROUND OF THE INVENTION

The heart of a computer's long term memory is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located on a slider that has an air bearing surface (ABS). The suspension arm biases the slider toward the surface of the disk, and when the disk rotates, air adjacent to the disk moves along with the surface of the disk. The slider flies over the surface of the disk on a cushion of this moving air. When the slider rides on the air bearing, the write and read heads are employed for writing magnetic transitions to and reading magnetic transitions from the rotating disk. The read and write heads are connected to processing circuitry that operates according to a computer program to implement the writing and reading functions.

The write head has traditionally included a coil layer embedded in first, second and third insulation layers (insulation stack), the insulation stack being sandwiched between first and second pole piece layers. A gap is formed between the first and second pole piece layers by a gap layer at an air bearing surface (ABS) of the write head and the pole piece layers are connected at a back gap. Current conducted to the coil layer induces a magnetic flux in the pole pieces which causes a magnetic field to fringe out at a write gap at the ABS for the purpose of writing the aforementioned magnetic transitions in tracks on the moving media, such as in circular tracks on the aforementioned rotating disk.

In recent read head designs, a GMR or TMR sensor has been employed for sensing magnetic fields from the rotating magnetic disk. The sensor includes a nonmagnetic conductive layer, or barrier layer, sandwiched between first and second ferromagnetic layers, referred to as a pinned layer and a free layer. First and second leads are connected to the sensor for conducting a sense current therethrough. The magnetization of the pinned layer is pinned perpendicular to the air bearing surface (ABS) and the magnetic moment of the free layer is located parallel to the ABS, but free to rotate in response to external magnetic fields. The magnetization of the pinned layer is typically pinned by exchange coupling with an antiferromagnetic layer.

The thickness of the spacer layer is chosen to be less than the mean free path of conduction electrons through the sensor. With this arrangement, a portion of the conduction electrons is scattered by the interfaces of the spacer layer with each of the pinned and free layers. When the magnetizations of the pinned and free layers are parallel with respect to one another, scattering is minimal and when the magnetizations of the pinned and free layer are antiparallel, scattering is maximized. Changes in scattering alter the resistance of the spin valve sensor in proportion to cos θ, where θ is the angle between the magnetizations of the pinned and free layers. In a read mode the resistance of the spin valve sensor changes proportionally to the magnitudes of the magnetic fields from the rotating disk. When a sense current is conducted through the spin valve sensor, resistance changes cause potential changes that are detected and processed as playback signals.

In order to meet the ever increasing demand for improved data rate and data capacity, researchers have recently been focusing their efforts on the development of perpendicular recording systems. A traditional longitudinal recording system, such as one that incorporates the write head described above, stores data as magnetic bits oriented longitudinally along a track in the plane of the surface of the magnetic disk. This longitudinal data bit is recorded by a fringing field that forms between the pair of magnetic poles separated by a write gap.

A perpendicular recording system, by contrast, records data as magnetizations oriented perpendicular to the plane of the magnetic disk. The magnetic disk has a magnetically soft underlayer covered by a thin magnetically hard top layer. The perpendicular write head has a write pole with a very small cross section and a return pole having a much larger cross section. A strong, highly concentrated magnetic field emits from the write pole in a direction perpendicular to the magnetic disk surface, magnetizing the magnetically hard top layer. The resulting magnetic flux then travels through the soft underlayer, returning to the return pole where it is sufficiently spread out and weak that it will not erase the signal recorded by the write pole when it passes back through the magnetically hard top layer on its way back to the return pole.

Although such perpendicular magnetic recording heads have the potential to increase data density over longitudinal recording system, the ever increasing demand for increased data rate and data density requires even further improvement in write head design. For example it is desirable to increase the write field gradient for better data error rate performance. One way to do this is to place a trailing shield adjacent to the trailing edge of the write pole. However, manufacturing limitations and design limitations have limited the performance of such a trailing shields, resulting in less than optimal write field and transition curvature. Therefore, there is a strong felt need for a write head design that can provide optimal write head performance, including optimal trailing shield performance. There is also a strong felt need for a practical method for manufacturing such a write pole having such an optimal design.

### SUMMARY OF THE INVENTION

The present invention provides a method for manufacturing a magnetic write head having a stepped trailing shield. The stepped trailing shield is formed by forming a non-magnetic bump over a write pole prior to electroplating a wrap-around magnetic shield. This bump is formed by constructing a mask having an opening configured to define the non-magnetic bump. A magnetic material is then sputter deposited. In order to decrease deposition of the non-magnetic material on the sides of the mask, a collimator is used to align the deposited material along a plane substantially parallel with an air bearing surface plane.

This collimation of the deposited non-magnetic material greatly facilitates liftoff by preventing the sides of the mask structure from being completely covered by the deposited non-magnetic material.

The collimation of the deposited material also advantageously prevents the formation of non-magnetic fences which would otherwise have to be removed by a harsh, aggressive process. If such fences were allowed to form, the aggressive processes used to remove them could damage the write pole and other important structures of the write head.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is an ABS view of a slider, taken from line 2-2 of FIG. 1, illustrating the location of a magnetic head thereon;

FIG. 3 is a cross sectional view of a magnetic head, taken from line 3-3 of FIG. 2 and rotated 90 degrees counterclockwise, of a magnetic write head according to an embodiment of the present invention;

FIG. 4 is an ABS view of a portion of the write head of FIG. 3; and

FIGS. 5-15 are views of a write head in various intermediate stages of manufacture illustrating method for manufacturing a write head according to an embodiment of the invention.

### DETAILED DESCRIPTION OF THE EMBODIMENTS

The following description is of the best embodiments presently contemplated for carrying out this invention. This description is made for the purpose of illustrating the general principles of this invention and is not meant to limit the inventive concepts claimed herein.

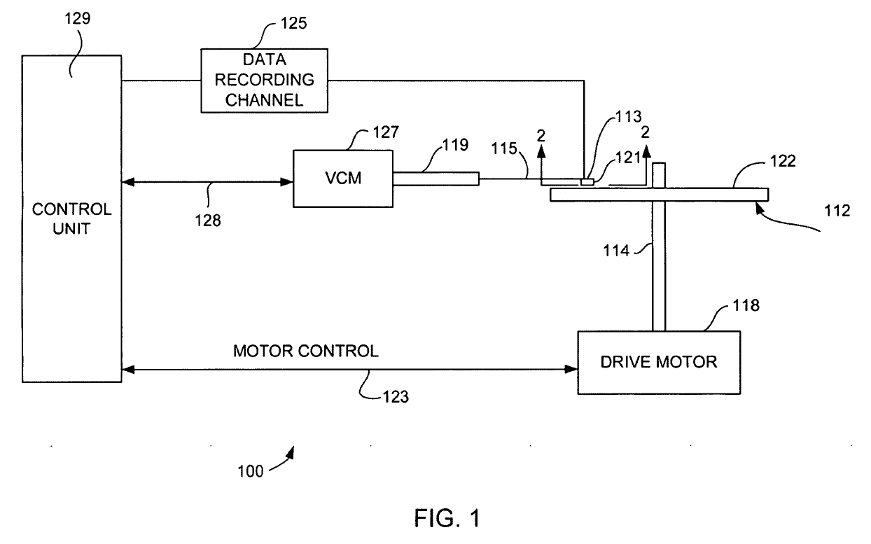

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 may access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122 which exerts an upward force or lift on the slider. The air bearing thus counter-balances the slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

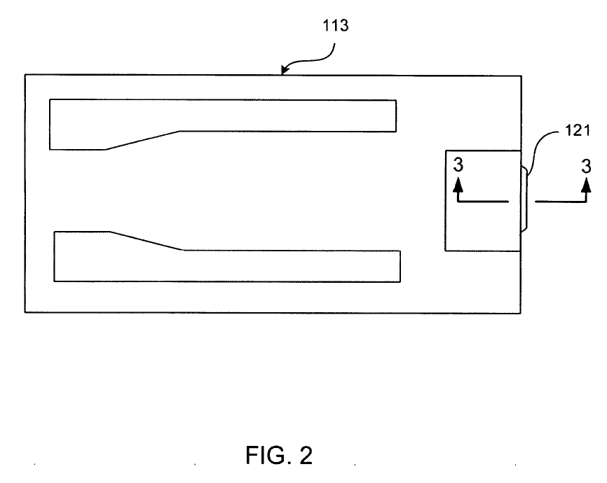

With reference to FIG. 2, the orientation of the magnetic head 121 in a slider 113 can be seen in more detail. FIG. 2 is an ABS view of the slider 113, and as can be seen the magnetic head including an inductive write head and a read sensor, is located at a trailing edge of the slider. The above description of a typical magnetic disk storage system, and the accompanying illustration of FIG. 1 are for representation purposes only. It should be apparent that disk storage systems may contain a large number of disks and actuators, and each actuator may support a number of sliders.

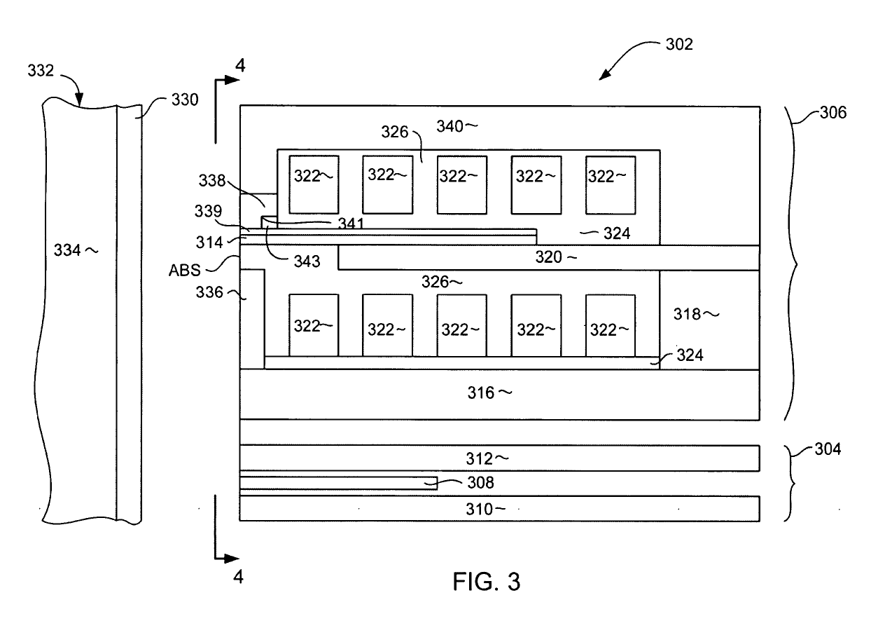

With reference now to FIG. 3, the invention can be embodied in a magnetic head 302. The magnetic head 302 includes a read head 304 and a write head 306. The read head 304 includes a magnetoresistive sensor 308, which can be a GMR, TMR, or some other type of sensor. The magnetoresistive sensor 308 is located between first and second magnetic shields 310, 312.

The write head 306 includes a magnetic write pole 314 and a magnetic return pole 316. The write pole 314 can be formed upon a magnetic shaping layer 320, and a magnetic back gap layer 318 magnetically connects the write pole 314 and shaping layer 320 with the return pole 316 in a region removed from the air bearing surface (ABS). A write coil 322 (shown in cross section in FIG. 3) passes between the write pole and shaping layer 314, 320 and the return pole 316, and may also pass above the write pole 314 and shaping layer 320. The write coil can be a helical coil or can be one or more pancake coils. The write coil 322 can be formed upon an insulation layer 324 and can be embedded in a coil insulation layer 326 such as alumina and or hard baked photoresist.

In operation, when an electrical current flows through the write coil 322. A resulting magnetic field causes a magnetic flux to flow through the return pole 316, back gap 318, shaping layer 320 and write pole 314. This causes a magnetic write field to be emitted from the tip of the write pole 314 toward a magnetic medium 332. The write pole 314 has a cross section at the ABS that is much smaller than the cross section of the return pole 316 at the ABS. Therefore, the magnetic field emitting from the write pole 314 is sufficiently dense and strong that it can write a data bit to a magnetically hard top layer 330 of the magnetic medium 332. The magnetic flux then flows through a magnetically softer under-layer 334, and returns back to the return pole 316, where it is sufficiently spread out and week that it does not erase the data bit recorded by the write head 314.

In order to increase write field gradient, and therefore, increase the speed with which the write head 306 can write data, a trailing magnetic shield 338 can be provided. The trailing magnetic shield 338 is separated from the write pole by a non-magnetic write gap 339, and may be connected with the shaping layer 320 and/or back gap 318 by a trailing return pole 340. The trailing shield 338 attracts the magnetic field from the write pole 314, which slightly cants the angle of the magnetic field emitting from the write pole 314. This canting of the write field increases the speed with which write-field polarity can be switched by increasing the field gradient.

With reference still to FIG. 3, the trailing shield 338 has a step 341 formed at its back edge away from the ABS. This step 341 is formed by a non-magnetic bump 343 that is strategically located between a portion of the trailing shield 338 and the trailing gap layer 339 and write pole 314. This step 341 improves the performance enhancing effects of the trailing shield by achieving better write field strength due to less flux shunting to the back of trailing shield 338 while also preventing magnetic saturation of the trailing shield. This step 341 and a method for manufacturing such a step will be discussed in greater detail below.

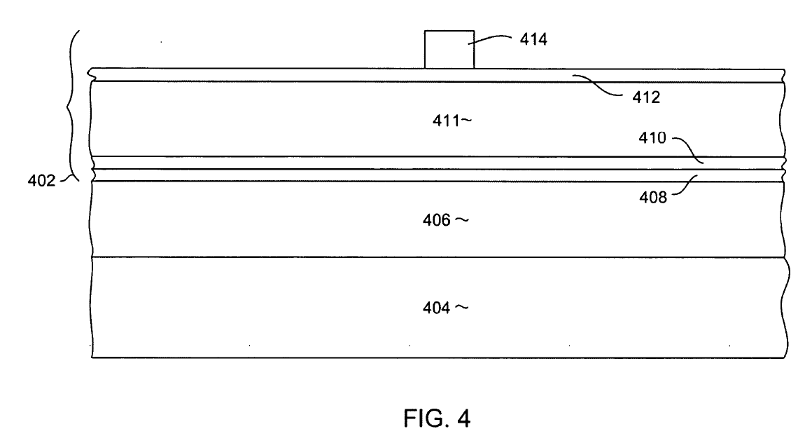

With reference now to FIGS. 4-15 a method is described for manufacturing a write head with a bump 343 and step 341. This method allows the front edge of the bump 343 (and therefore the step 341) to be accurately located relative to the back edge of the shield 338, as will be seen. With particular reference to FIG. 4, a substrate 404 is provided. The substrate 404 may include the insulation layer 326 and a portion of the shaping layer 320 described above with reference to FIG. 3. A magnetic write pole material 406 is deposited over the substrate 404. The magnetic write pole material 406 is preferably a lamination of magnetic layers separated by thin non-magnetic layers. A mask structure 402, constructed of a series of mask layers is deposited over the magnetic write pole material. The mask structure 402 includes a first hard mask layer 408, which is preferably alumina, deposited over the magnetic write pole material. This hard mask layer 408 is preferably deposited to a thickness that will define a trailing gap in the finished head. A second hard mask layer 410 is deposited over the first hard mask layer. The second hard mask layer is constructed of a material that can be removed by Reactive Ion Etching (RIE) such materials being referred to herein as “RIEable” materials. An image transfer layer 411 can be deposited over the RIEable second hard mask layer 410. The image transfer layer can be constructed of a soluble polyimide material such as DURAMIDE®. A third hard mask layer 412, such as SiO₂, may also be deposited over the image transfer layer 411. A photoresist layer 414 is then deposited over the other underlying mask layers 408-412, and is photolithographically patterned to define a write pole shape, which is shown in cross section in FIG. 4.

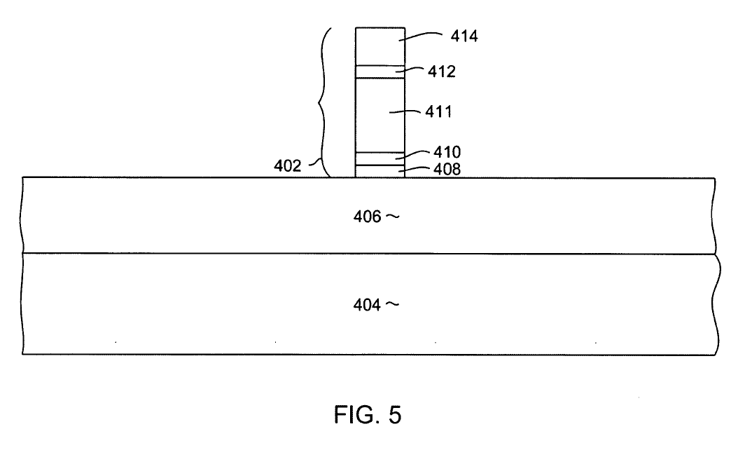

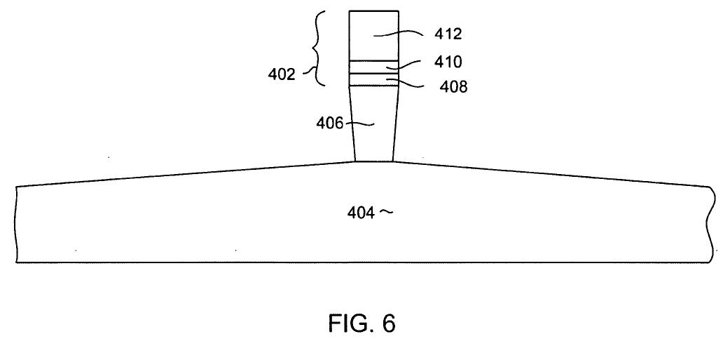

With reference now to FIG. 5, a reactive ion etching (RIE) is performed to transfer the image of the photoresist mask 414 onto the underlying mask layers 408-412 by removing portions of the layers 408-412 that are not protected by the mask 414. Then, an ion milling operation is performed to remove portions of the magnetic write pole material 406 that are not protected by the mask structure. The ion milling can be performed at one or more angles relative to normal in order to form a write pole 406 having a trapezoidal shape as shown in FIG. 6. Also, as shown in FIG. 6, a portion of the mask structure 402 will be consumed by the ion milling process, leaving the first and second hard mask layers 408, 410 and possibly a portion of the image transfer layer 412.

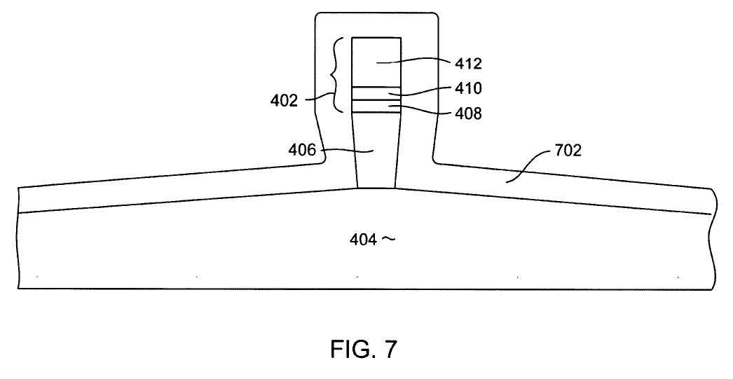

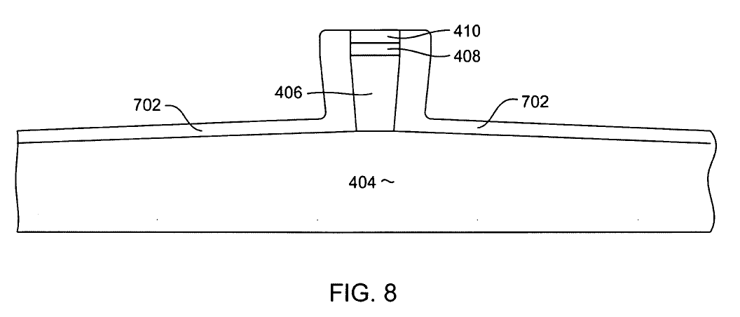

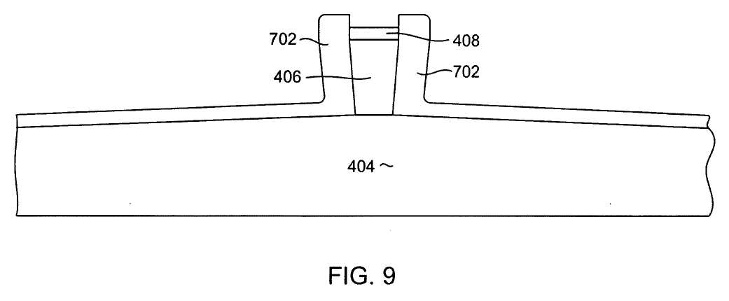

With reference now to FIG. 7, a layer of non-magnetic sidewall material 702 is deposited. The non-magnetic side wall material 702 is preferably alumina and is preferably deposited by a conformal deposition process such as atomic layer deposition or chemical vapor deposition. Then a material removal process is performed to preferentially remove horizontally disposed portions of the non-magnetic gap layer 702 leaving vertical, non-magnetic side gap walls 702 at either side of the write pole 406 as shown in FIG. 8. The material removal process can be, for example, reactive ion milling (RIM) or could include refilling with a RIEable fill layer, performing a chemical mechanical polishing process and then performing a reactive ion etching to remove the RIEable fill layer. Then, a reactive ion etching can be performed to remove the RIEable hard mask layer 410, leaving a structure as shown in FIG. 9.

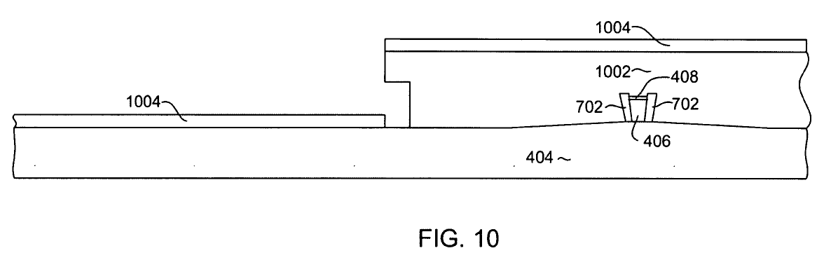

With reference now to FIG. 10, a bi-layer photoresist mask 1002 is formed to cover a region where the write pole 406 is, but leaving a region open where an electrical lapping guide (ELG) will be formed. A non-magnetic metal 1004 is then deposited full film. The non-magnetic metal 1004 can be, for example, Ru, Au, Ir, Rh, etc. The bi-layer mask 1002 can then be lifted off. The bi-layer shape of the mask 1002 facilitates liftoff, when the mask has been covered with the non-magnetic metal 1004.

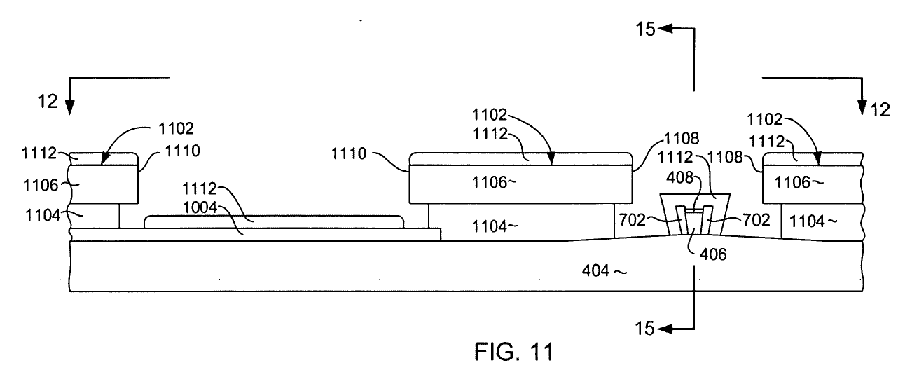

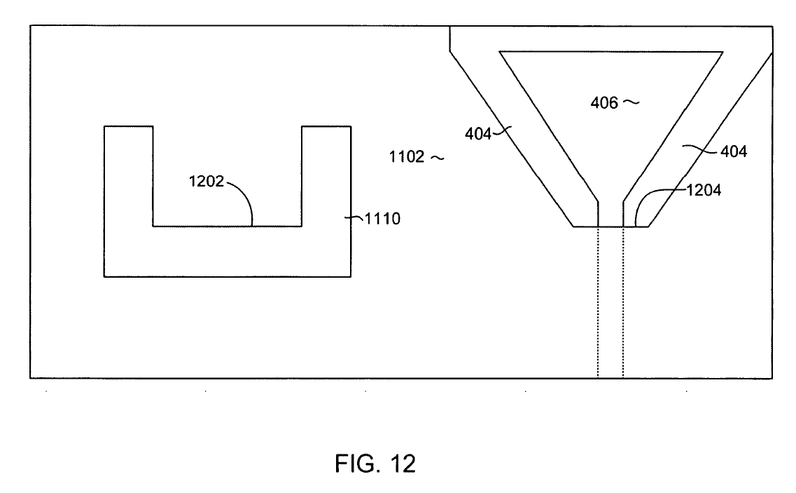

With reference now to FIG. 11, a bi-layer mask structure 1102 is formed. The bi-layer mask 1102 can include a liftoff layer 1104, constructed of a soluble polyimide material such as polymethylglutarimide and a photolithographically patterned photoresist layer 1106. The mask 1102 has first and second openings 1108, 1110. The first opening 1108 is formed over the write pole 406 and defines a non-magnetic bump structure (e.g. non-magnetic bump 343 in FIG. 3). The second opening 1110 is formed in an electrical lapping guide region, away from the write head 406 and defines an electrical lapping guide. A possible configuration of the openings 1108, 1110 can be seen more clearly with reference to FIG. 12, which shows a top down view as viewed from line 12-12 of FIG. 11. With reference again to FIG. 11, a non-magnetic material 1112 is deposited, such as by sputter deposition so that it covers the mask 1102 and is also deposited into the openings 1108, 1110. The non-magnetic material can be alumina, TaO or some other non-magnetic material. After deposition of the non-magnetic material 1112, the mask structure 1102 can be lifted off. The bi-layer structure of the mask 1102 facilitates this lift off. It should be pointed out that the top-down view shown in FIG. 12, is shown prior to deposition of the non-magnetic material in order to more clearly show the openings 1108, 1110 in the mask structure 1102. The deposition of the non-magnetic material 1112 will be described in greater detail below.

With reference to FIG. 12, it can be seen that the second opening 1110 has a back edge 1202 that is aligned relative to a front edge 1204 of the first opening 1108. The second opening 1110 defines an electrical lapping guide, and the first opening defines a non-magnetic bump. Therefore, the electrical lapping guide defined by the second opening 1110 will be useful for accurately locating the front edge of the non-magnetic bump 1204, as will be seen below.

During deposition of the non-magnetic material 1112 it is desirable that the non-magnetic material be deposited on the sides and top of the write pole 406 trailing gap layer 408 and side gaps 702. However, it is not desirable for the non-magnetic material to deposit excessively on the sides of the mask structure 1102, as this will make liftoff of the mask more difficult and will result in the formation of non-magnetic fences which will have to be later removed. The present invention, as described below, deposits this magnetic material in a manner that avoids deposition of the non-magnetic material 1112 on the sides of the mask 1102, thereby facilitating mask liftoff and avoiding fence formation.

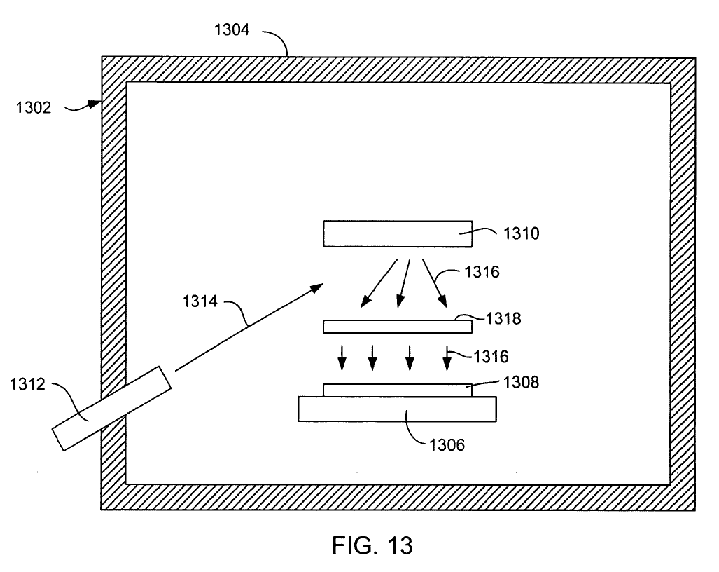

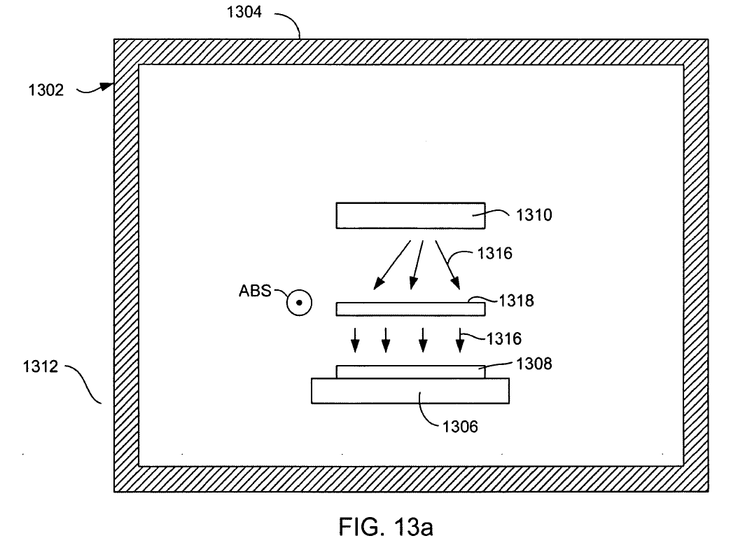

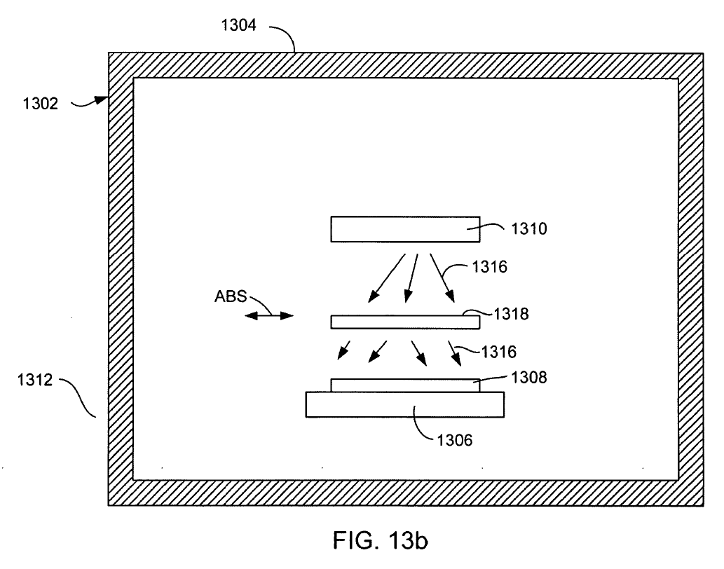

With reference now to FIGS. 13a and 13b, the non-magnetic bump material 1112 (FIG. 11) is deposited in a sputter deposition tool 1302. The sputter deposition tool 1302 can include a chamber 1304, in which is mounted a chuck 1306. The chuck supports a wafer 1308, on which many thousands of write heads will be formed. A target 1310 is held within the chamber, the target 1310 being constructed of the material that is to be deposited onto the wafer. For example, the target 1310 could be aluminum, aluminum oxide, tantalum or tantalum oxide. As can be seen, the atoms 1316 being dislodged from the target are initially oriented in a random manner scattering in all directions. The collimator 1318 aligns the direction of travel of the dislodged ions 1316 so that they travel primarily along a desired plane. FIG. 13a shows a view of the wafer perpendicular to the air bearing surface (ABS) as indicated by arrow head symbol ABS, and FIG. 13b shows a view of the wafer with the ABS surface oriented parallel with the page as indicated by double headed arrow symbol ABS. As can be seen, then, the collimator aligns the deposited atoms 1316 so that they are substantially vertical in a plane perpendicular to the ABS, while they are free to scatter in a plane parallel with the ABS.

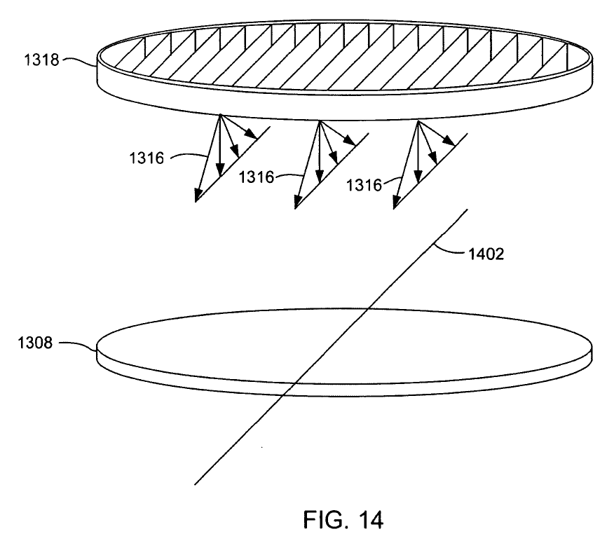

This can be seen more clearly with reference to FIG. 14, which shows an enlarged perspective view of the collimator 1318 and wafer 1308. The orientation of the desired ABS plane (i.e. the direction of orientation of the rows of sliders) is indicated by line 1402. As can be seen, the collimator orients the dislodged ions 1316 so that they travel primarily along a plane oriented parallel with the direction of the desired ABS plane and parallel with the orientation of the rows of sliders.

Referring back to FIG. 11, it can be seen that the sides of the write pole 406 and side gap layers 702 are oriented substantially perpendicular to the air bearing surface plane (ABS). FIG. 11 is a cross sectional view of a portion of a wafer, with the cross section being in a plane parallel with the ABS. Therefore, the use of a collimator 1318 (FIG. 13) facilitates the deposition of the non-magnetic bump material 1112 on the top and sides of the write pole 406, side gaps 702 and trailing gap while minimizing deposition on the side edges of the mask openings 1108 such as side edge 1204, which can be seen more clearly with reference to FIG. 12.

After the deposition of the non-magnetic bump material 1112, the mask structure 1102 can be lifted off. As mentioned above, the use of the collimator 1318 (FIG. 13) during deposition facilitates liftoff and avoids the formation of fences which would otherwise have to be removed by an aggressive material removal process that could damage other components of the write head.

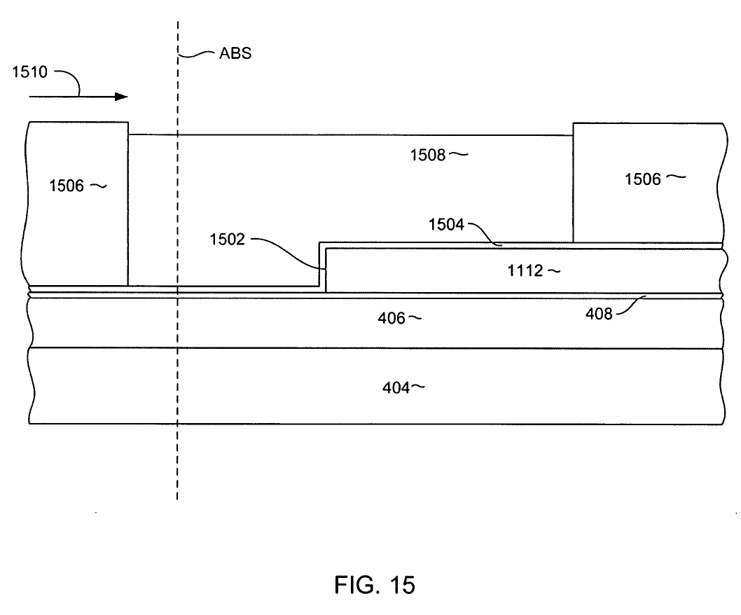

With reference now to FIG. 15, a side cross sectional view shows the write pole 406 and trailing magnetic gap layer 408. As can be seen, the above process forms a non-magnetic bump 1112 having a front edge 1502 defined by the mask structure 1102 (FIG. 1204. In order to form a trailing magnetic shield, a seed layer 1504 is deposited and an electroplating frame mask 1506 is formed. A magnetic material 1508 such as NiFe or CoFe is then deposited by electroplating to form the magnetic trailing shield 338 described above with reference to FIG. 3.

Also, after lifting off the mask 1102 a material removal process such as ion milling can be performed to remove portions of the non-magnetic metal 1004 that are not protected by the non magnetic material 1112, thereby using the non-magnetic material 1112 as a mask to define an electrical lapping guide (ELG) from the non-magnetic metal 1004.

After the write head been completed, the wafer 1308 (FIG. 14) will be cut into rows of sliders, and a lapping operation will be performed to remove material from the direction indicated by arrow 1510 in FIG. 15. The amount of material removed during this lapping process determines the location of the front edge 1502 of the bump 1112 from the air bearing surface (ABS). The location of the intended air bearing surface plane is indicated by the dashed line denote “ABS”. With reference to FIG. 12, the electrical lapping guide 1110 can be used to accurately determine the amount by which lapping has progressed and to indicate when lapping should be terminated. As the lapping process removes material from the front edge of the electrical lapping guide 1110 the electrical resistance of the lapping guide 1110 increases. This increase in resistance, therefore, corresponds to the lapping progress. Because the lapping guide 1110 was defined and formed in the same manufacturing processes used to define the non-magnetic bump 1112, the lapping guide 1110 provides an accurate indication of the distance between the ABS and the front edge 1502 of the bump 1112. While various embodiments have been described, it should be understood that they have been presented by way of example only, and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a magnetic write head comprising:
forming a write pole on a substrate;
forming a mask structure over the write pole and substrate; and
depositing a non-magnetic bump material and passing the non-magnetic bump material through a collimator.

2. A method as in claim 1 wherein the write pole is oriented relative to an intended air bearing surface plane, and wherein the collimator is arranged so as to cause the deposited, non-magnetic write pole material to be deposited along a plane that is substantially parallel with the air bearing surface plane.

3. A method as in claim 1 further comprising, after forming the write pole, forming first and second non-magnetic side gap layers on first and second sides of the write pole and forming a trailing non-magnetic gap layer on a trailing surface of the write pole.

4. A method as in claim 1 wherein the mask structure includes first and second openings, the first opening being over a portion of the write pole and configured to define a non-magnetic bump, the second opening being away from the write pole and configured to define an electrical lapping guide.

5. A method as in claim 1 further comprising, after depositing the non-magnetic bump material removing the mask structure and electroplating a magnetic shield, a portion of the magnetic shield being disposed over at least a portion of the non-magnetic bump.

6. A method as in claim 1 wherein the mask structure is a bi-layer mask structure.

7. A method as in claim 1 wherein the non-magnetic bump material comprises a material selected from the group consisting of alumina and TaO.

8. A method as in claim 1 wherein the non-magnetic bump material is deposited by sputter deposition.

9. A method as in claim 4 wherein the write pole and lapping guide are formed on a wafer, the method further comprising, after depositing the non-magnetic bump material, slicing the wafer into rows of sliders, and performing a lapping operation on one of the rows of sliders while measuring an electrical resistance of the electrical lapping guide, and terminating the lapping when the electrical resistance of the electrical lapping guide reaches a predetermined level.

10. A method as in claim 5 wherein the non-magnetic bump has a front edge, and wherein the magnetic shield is formed to have a back edge formed behind the front edge of the bump and a front edge in front of the front edge of the bump.

11. A method as in claim 1 wherein the mask has an edge and wherein the collimator aligns the deposited material to decrease deposition of the non-magnetic bump material on the edge of the mask structure.

12. A method for manufacturing a magnetic write head, comprising:
placing a wafer in a sputter deposition tool;
forming a write pole on the wafer;
forming a mask structure having an opening over a portion of the write pole;
placing a target in the sputter deposition tool;
placing a collimator in the sputter deposition tool, between the target and the wafer; and
directing an ion beam from an ion beam gun at the target.

13. A method as in claim 12 further comprising, after forming a write pole on the wafer, forming non-magnetic side walls and a non-magnetic trailing gap on a portion of the write pole.

14. A method as in claim 12 further wherein the target comprises a magnetic material.

15. A method as in claim 12 wherein the target comprises aluminum or Ta.

16. A method as in claim 12 wherein the target comprises alumina or TaO.

17. A method as in claim 12 wherein an orientation of the write pole on the wafer defines an air bearing surface plane and wherein the collimator is arranged to orient deposited material from the target along a plane substantially parallel with the air bearing surface plane.

18. A method as in claim 12 wherein the mask has a second opening, away from the write pole, that defines an electrical lapping guide.

19. A method as in claim 12 wherein the mask has a second opening, away from the write pole, that defines an electrical lapping guide, the method further comprising:
forming a lapping guide as defined by the second opening in the mask structure;
removing the wafer from the sputter deposition tool;
slicing the wafer into rows of sliders; and
performing a lapping operation while measuring an electrical resistance of the lapping guide to determine when lapping should be terminated.

20. A method as in claim 12 wherein the collimator aligns deposited non-magnetic material to decrease deposition of the non-magnetic material on a side of the masks structure.
